(19) United States
(12) Patent Application Publication
(10) Pub. No.: US 2004/0101622 A1
(43) Pub. Date: May 27, 2004

(54) Method of depositing thin film using aluminum oxide

(76) Inventors: Young Hoon Park, Pyungtaek-city (KR); Cheol Hyun Ahn, Pyungtaek-city (KR); Hong Joo Lim, Pyungtaek-city (KR); Sang Kyu Lee, Pyungtaek-city (KR); Jang Ho Bae, Pyungtaek-city (KR)

Correspondence Address: CANTOR COLBURN, LLP, 55 GRIFFIN ROAD SOUTH, BLOOMFIELD, CT, 06002

(21) Appl. No.: 10/716,950

(22) Filed: Nov. 19, 2003

(30) Foreign Application Priority Data
Nov. 20, 2002 (KR) 2002-72380

(51) Int. Cl. C23C 14/00; C23C 16/00; H01L 21/31

(52) U.S. Cl. 427/255.26; 438/758

(57) ABSTRACT

Provided is a method of depositing a thin film on a wafer using an aluminum compound. The method includes (S1) mounting the wafer on the wafer block; and (S2) depositing an Al₂O₃ thin film. Step (S2) includes (S2-1) feeding ozone by spraying ozone through the first spray holes and spraying an inert gas through the second spray holes; (S2-2) purging the ozone by stopping the spraying of the ozone, spraying the inert gas through the first spray holes, and spraying the same inert gas as in step (S2-1) through the second spray holes; (S2-3) feeding TMA by spraying the TMA, which is transferred by a carried gas, through the second spray holes and spraying the inert gas through the first spray holes; and (S2-4) purging the TMA by stopping the spraying of the TMA, spraying the same carrier gas as in step (S2-3) through the second spray holes, and spraying the same inert gas as in step (S2-3) through the first spray holes. Step (S2) is performed by repeating an ALD cycle of steps (S2-1), (S2-2), (S2-3), and (S2-4) twice or more.

This application claims the priority of Korean Patent Application No. 2002-72380, filed on Nov. 20, 2002, in the Korean Intellectual Property Office, the disclosure of which is incorporated herein in its entirety by reference.

### BACKGROUND OF THE INVENTION

1. Field of the Invention

The present invention relates to a method of depositing a thin film, and more particularly, to a method of depositing an aluminum oxide thin film on a wafer using ozone and trimethylaluminum (TMA).

2. Description of the Related Art

To deposit an aluminum oxide (Al₂O₃) film, each monatomic film is deposited by an atomic layer deposition (ALD) process, in which ozone and TMA are alternately fed into a reaction chamber in which a wafer is loaded and alternately purged. A conventional method of depositing an aluminum oxide film is disclosed in Korean Patent Application No. 1999-058541 by the present inventor. An aluminum oxide film deposited on a wafer should have a uniform thickness and its degree of purity should be sufficiently high so as to increase the yield of semiconductor devices and improve the quality thereof. Therefore, laborious research has progressed to enhance thickness uniformity and degree of purity.

### SUMMARY OF THE INVENTION

The present invention provides a method of depositing a thin film using an aluminum compound, which improves the thickness uniformity and electric characteristics of an aluminum oxide (Al₂O₃) film deposited on a wafer.

In accordance with an aspect of the present invention, there is provided a method of depositing a thin film on a wafer using an aluminum compound. In the method, an Al₂O₃ thin film is deposited using a reaction chamber comprising a reactor block in which a wafer block is received; a top lid for covering the reactor block to maintain a predetermined pressure; a shower head including a plurality of first spray holes-for spraying a first reactive gas supplied from a gas supply portion on the wafer and a plurality of second spray holes for spraying a second reactive gas supplied from the gas supply portion on the wafer.

The method of the present invention comprises (S1) mounting the wafer on the wafer block that is set so as to heat the wafer at a temperature of 250° C. or higher; and (S2) depositing an Al₂O₃ thin film by alternately spraying the first reactive gas and the second reactive gas on the wafer.

Step (S2) may comprise (S2-1) feeding ozone, (S2-2) purging the ozone, (S2-3) feeding a TMA gas, and (S2-4) purging the TMA gas.

In step (S2-1), the ozone as the first reactive gas is sprayed through the first spray holes at a flow rate of 50 sccm to 1000 sccm. At the same time, an inert gas is sprayed through the second spray holes at a flow rate of 50 sccm to 1000 sccm. Here, the concentration of the ozone may be 100 g/cm³ or higher. In step (S2-2), the spraying of the ozone is stopped and the inert gas is sprayed through the first spray holes at a flow rate of 50 sccm to 1000 sccm. At the same time, the same inert gas as in step (S2-1) is sprayed through the second spray holes. In step (S2-3), the TMA gas as the second reactive gas is sprayed through the second spray holes and transferred by a carrier gas that is supplied at a flow rate of 50 sccm to 1000 sccm. At the same time, the inert gas is sprayed through the first spray holes at a flow rate of 50 sccm to 1000 sccm. Also, in step (S2-4), the spraying of the TMA gas is stopped and the same carrier gas as in step (S2-3) is sprayed through the second spray holes. At the same time, the same inert gas as in step (S2-3) is sprayed through the first spray holes. Step (S2) may be performed by repeating an ALD cycle of steps (S2-1), (S2-2), (S2-3), and (S2-4) twice or more.

Herein, it is set that steps (S2-1) and (S2-2) each is performed for 0.1 second to 4 seconds and steps (S2-3) and (S2-4) each is performed for 0.1 second to 3 seconds.

The inert gas may be sprayed through gas curtain holes, which are further included in the shower head, toward the inner sidewalls of the reactor block so as to minimize deposition of the thin film on the inner sidewalls of the reactor block, and the inert gas may be supplied at a flow rate of 50 sccm or more.

The TMA gas may be supplied from a canister that is heated at a temperature of approximately 16° C. to 40° C. and has a capacity of approximately 500 cc to 3000 cc.

Also, the method of the present invention may further comprise vacuum purging, which is selectively performed between any two steps of the ALD cycle of steps (S2-1), (S2-2), (S2-3), and (S2-4). Vacuum purging may be performed by preventing all the gases from flowing into the reaction chamber, and it is set that vacuum purging is performed for 0.1 second to 4 seconds.

### BRIEF DESCRIPTION OF THE DRAWINGS

The above and other features and advantages of the present invention will become more apparent by describing in detail preferred embodiments thereof with reference to the attached drawings in which:

FIG. 1 is a construction diagram of a thin film deposition apparatus, in which a thin film is deposited according to the present invention;

FIG. 2 is a graph illustrating a method of depositing a thin film according to an embodiment of the present invention;

FIG. 3 is a graph showing that the thickness of a thin film is linearly proportional to the number of cycles in the present invention;

FIG. 4 is a diagram showing that the thickness uniformity is improved as the flow rate of ozone increases; and

FIG. 5 is a graph illustrating a method of depositing a thin film according to another embodiment of the present invention.

### DETAILED DESCRIPTION OF THE INVENTION

Hereinafter, a method of depositing a thin film using an aluminum compound according to the present invention will now be described more fully with reference to the accompanying drawings, in which preferred embodiments of the invention are shown.

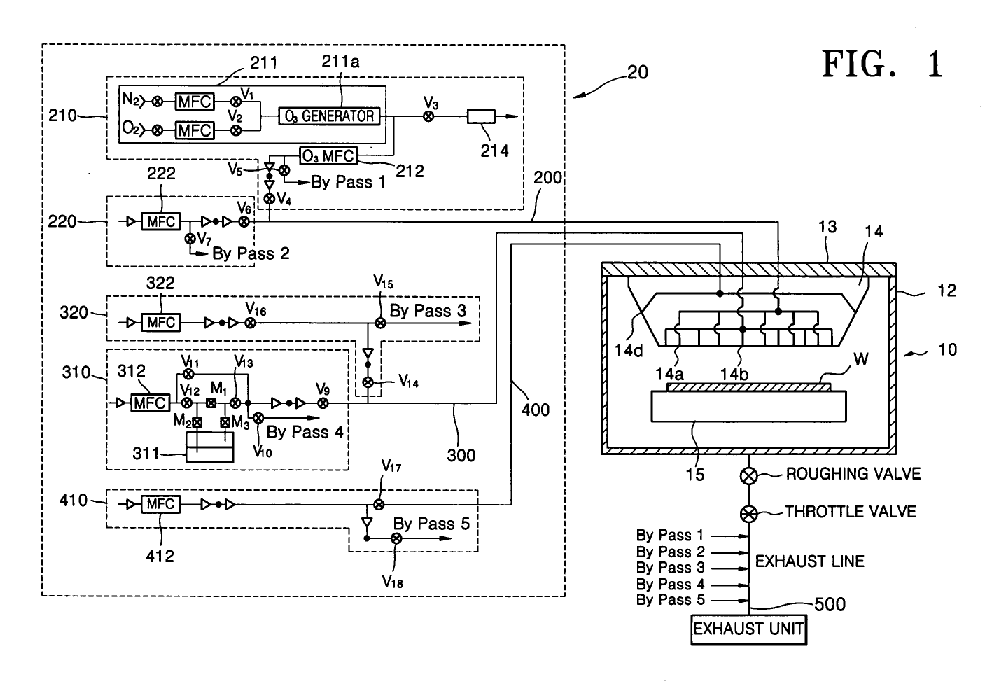

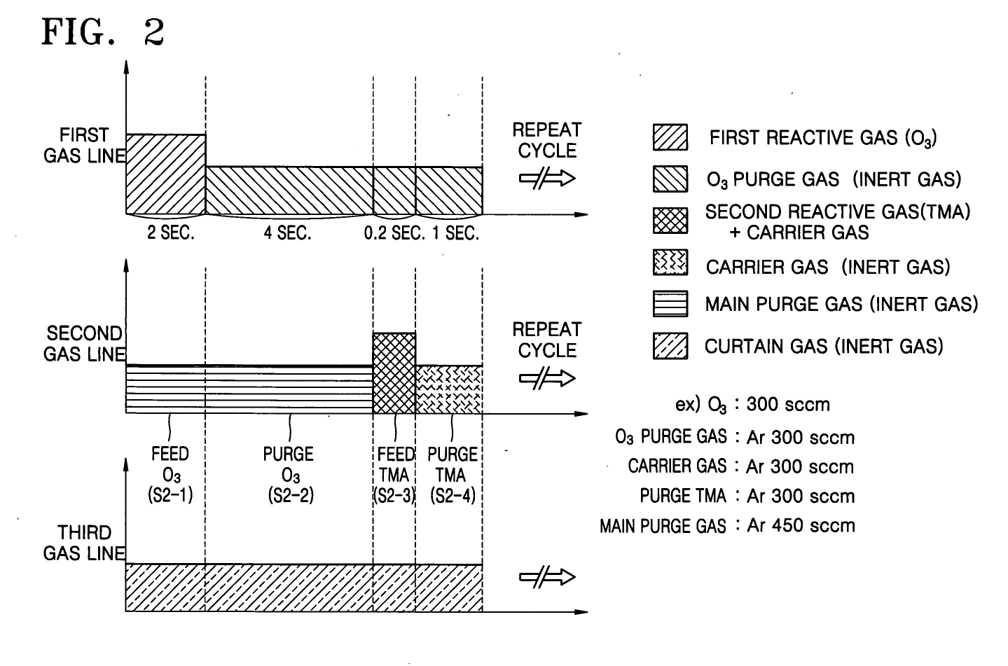

FIG. 1 is a construction diagram of a thin film deposition apparatus, in which a thin film is deposited according to the present invention, and FIG. 2 is a graph illustrating a method of depositing a thin film according to an embodiment of the present invention.

Referring to FIG. 1, a thin film deposition apparatus, in which an aluminium thin film is deposited according to the present invention, comprises a reaction chamber 10, in which one or more wafers w are loaded, and a gas supply portion 20 for supplying reactive gases to the reaction chamber 10.

The reaction chamber 10 comprises a reactor block 12 including a wafer block 15 on which one or more wafers w are mounted, a top lid 13 for covering the reactor block 12 to maintain a predetermined pressure, and a shower head 14 installed under the top lid 13. Here, the shower head 14 comprises a plurality of first spray holes 14a for spraying a first reactive gas on a wafer w, a plurality of second spray holes 14b for spraying a second reactive gas on the wafer w, and a plurality of gas curtain holes for spraying a curtain gas (an inert gas) toward the inner sidewalls of the reactor block 12 so as to minimize deposition of the thin film on the inner sidewalls of the reactor block 12.

The gas supply portion 20 comprises a first reactive gas supply portion 210 for supplying ozone (O₃) as the first reactive gas to a first gas line that is connected to the first spray holes 14a, an ozone purge gas supply portion for supplying an ozone purge gas (the inert gas) to the first gas line 200, a second reactive gas supply portion 310 for supplying trimethylaluminum (TMA) as the second reactive gas to a second gas line 300 that is connected to the second spray holes 14b, a main purge gas supply portion 320 for supplying a main purge gas (the inert gas) to the second gas line, and a curtain gas supply portion 410 for supplying a curtain gas (the inert gas) to a curtain gas line 400 that is connected to the gas curtain holes 14d, in order to form a gas curtain on the inner sidewalls of the reactor block 12.

The first reactive gas supply portion 210 comprises an ozone generating unit 211 for generating ozone, an ozone MFC 212 for controlling the flow of ozone generated from the ozone generating unit 211, an ozone feeding valve V4 for turning on and off the flow of ozone from the ozone MFC 212 into the first gas line 200, an ozone feeding bypass valve V5 for allowing ozone to bypass the reaction chamber 10 and turning on and off the flow of ozone from the ozone MFC 212 directly into an exhaust line 500.

The ozone generating unit 211 includes an ozone generator 211a for generating ozone using oxygen (O₂) and nitrogen (N₂) that are supplied to the ozone generating unit 211 through the MFC and valves V1 and V2. The excessively generated ozone flows through an ozone bypass valve V3 and an ozone remover 214 and is exhausted to the atmosphere.

The ozone purge gas supply portion 220 comprises an ozone purge gas MFC 222 for controlling the flow rate of the ozone purge gas (the inert gas), an ozone purge valve V6 for turning on and off the flow of the ozone purge gas from the ozone purge gas MFC 222 into the first gas line 200, and an ozone purge bypass valve V7 for allowing the ozone purge gas to bypass the reaction chamber 10 and turning on and off the flow of the ozone purge gas from the ozone purge gas MFC 222 directly into the exhaust line 500.

The second reactive gas supply portion 310, a kind of liquid material bubbler, comprises a canister 311 in which TMA as a liquid material of the second reactive gas is contained, a carrier gas MFC 312 for controlling the flow rate of a carrier gas (the inert gas) that flows into the canister 311, a TMA feeding valve V9 for turning on and off the flow of a TMA gas from the canister 311 into the second gas line 300, a TMA bypass valve V10 for allowing a TMA gas to bypass the reaction chamber 10 and turning on and off the flow of the TMA gas from the canister 311 directly into the exhaust line 500, and a canister bypass valve V11 for allowing the carrier gas to bypass the reaction chamber 10 and turning on and off the flow of the carrier gas from the carrier gas MFC 312 directly into the second gas line 300. A valve V12 is installed between the carrier gas MFC 312 and the canister 311, and a valve V13 is installed between the canister 311 and the second gas line 300. A manual valve M1 is installed between the valves V12 and V13, a manual valve M2 is installed between the valve V12 and the canister 311, and a manual valve M3 is installed between the valve V13 and the canister 311. Here, the canister 311 in which the TMA is contained is heated at a temperature of approximately 16° C. to 40° C. and has a capacity of approximately 500 cc to 3000 cc. In the present embodiment, the canister 311 is heated at a temperature of 25° C. and has a capacity of 1000 cc.

The main purge gas supply portion 320 comprises a main purge gas MFC 322 for controlling the flow rate of the main purge gas (the inert gas), a main purge valve V14 for turning on and off the flow of the main purge gas from the main purge MFC 332 into the second gas line 300, and a main purge bypass valve V15 for allowing the main purge gas to bypass the reaction chamber 10 and turning on and off the flow of the main purge gas from the main purge gas MFC 322 directly into the exhaust line 500.

The curtain gas supply portion 410 comprises a curtain gas MFC 412 for controlling the flow rate of the curtain gas (the inert gas), a curtain gas valve V17 for turning on and off the flow of the curtain gas from the curtain gas MFC 412 into the curtain gas line 400, and a curtain gas bypass valve V18 for allowing the curtain gas to bypass the reaction chamber 10 and turning on and off the flow of the curtain from the curtain gas MFC 412 directly into the exhaust line 500.

Although the flow rates of gases are controlled using MFCs in the present embodiment, it is possible to use known needle valves instead.

Hereinafter, a method of depositing an Al₂O₃ thin film using the foregoing thin film deposition apparatus will be described.

The depositing of an Al₂O₃ thin film on a wafer w comprises (S1) mounting the wafer w on the wafer block 15 and (S2) depositing the Al₂O₃ thin film by spraying reactive gases on the wafer w.

In step (SI), a robot arm (not shown) loads the wafer w out of a transfer module (not shown) into the reaction chamber 10 to mount the wafer w on the wafer block 15. In this step, the wafer block 15 previously heats the waferw to a temperature of 250° C. or more. In the present embodiment, the wafer w is a wafer with a diameter of 300 mm.

Step (S2) is performed by repeating a cycle of (S2-1) feeding ozone, (S2-2) purging the ozone, (S2-3) feeding TMA, and (S2-4) purging the TMA once or more. Step (S2) will be described in detail now.

In step (S2-1), ozone, the flow rate of which is controlled by the ozone MFC 212, flows through the ozone feeding valve V4, the first gas line 200, and the first spray holes 14a and is sprayed on the wafer w. At the same time, the main purge gas (the inert gas), the flow rate of which is controlled by the main purge gas MFC 322, flows through the main purge valve V14, the second gas line 300, and the second spray holes 14b and is sprayed on the wafer w. Here, the concentration of the ozone is 100 g/cm³ or higher and the flow rate of the ozone ranges from 50 sccm to 1000 sccm. The flow rate of the main purge gas ranges from 50 sccm to 1000 sccm. In the present embodiment, the flow rate of each of the ozone and the main purge gas is 300 sccm.

In step (S2-2), the spraying of the ozone is stopped, the ozone purge gas (the inert gas), the flow rate of which is controlled by the ozone purge gas MFC 222, flows through the ozone purge valve V6, the first gas line 200, and the first spray holes 14a and is sprayed into the reaction chamber 10. At the same time, the same main purge gas as in step (S2-1) is sprayed on the wafer w through the second spray holes 14b. Here, the flow rate of the ozone purge gas ranges from 50 sccm to 1000 sccm. In the present embodiment, the flow rate of the ozone purge gas is 300 sccm.

In step (S2-3), the carrier gas (the inert gas), the flow rate of which is controlled by the carrier gas MFC 312, flows through the canister 311 to transfer a TMA gas. The TMA gas, transferred by the carrier gas, flows through the TMA feeding valve V9, the second gas line 300, and the second spray holes 14b and is sprayed on the wafer w. At the same time, the ozone purge gas is sprayed on the wafer w through the first spray holes 14a. Here, the flow rate of the carrier gas ranges from 50 sccm to 1000 sccm, and the flow rate of the ozone purge gas ranges from 50 sccm to 1000 sccm. In the present embodiment, the flow rate of each of the carrier gas and the ozone purge gas is 300 sccm.

In step (S2-4), the spraying of the TMA gas is stopped, and the same carrier gas as in step (S2-3) bypasses the canister 311 and is sprayed on the wafer w through the second spray holes 14b. At the same time, the same ozone purge gas as in step (S2-3) is sprayed through the first spray holes 14a.

While the Al₂O₃ thin film is being deposited, a curtain gas (the inert gas), the flow rate of which is controlled by the curtain gas MFC 412, flows through the curtain gas valve V17, the curtain gas line 400, and the gas curtain holes 14d and is preferably sprayed so as to minimize deposition of the thin film on the inner sidewalls of the reactor block 12. Here, the flow rate of the curtain gas is preferably 50 sccm or more. In the present embodiment, the flow rate of the curtain gas is 450 sccm. The curtain gas forms a gas curtain in the reaction chamber 10 so as to minimize deposition of the thin film on the inner sidewalls of the reaction chamber 10. Thus, a cleaning cycle of the reaction chamber can be extended.

Also, steps (S2-1) and (S2-2) each are performed for 0.1 second to 4 seconds. In the present embodiment, step (S2-1) is performed for 2 seconds, and step (S2-2) is performed for 4 seconds. Also, steps (S2-3) and (S2-4) each are performed for 0.1 second to 3 seconds. In the present embodiment, step (S2-3) is performed for 0.2 second, and step (S2-4) is performed for 1 second.

As described above, in step (S2), a cycle of (S2-1) feeding ozone, (S2-2) purging the ozone, (S2-3) feeding TMA, and (S2-4) purging the TMA is repeated once or more until an aluminium oxide film is formed to a desired thickness.

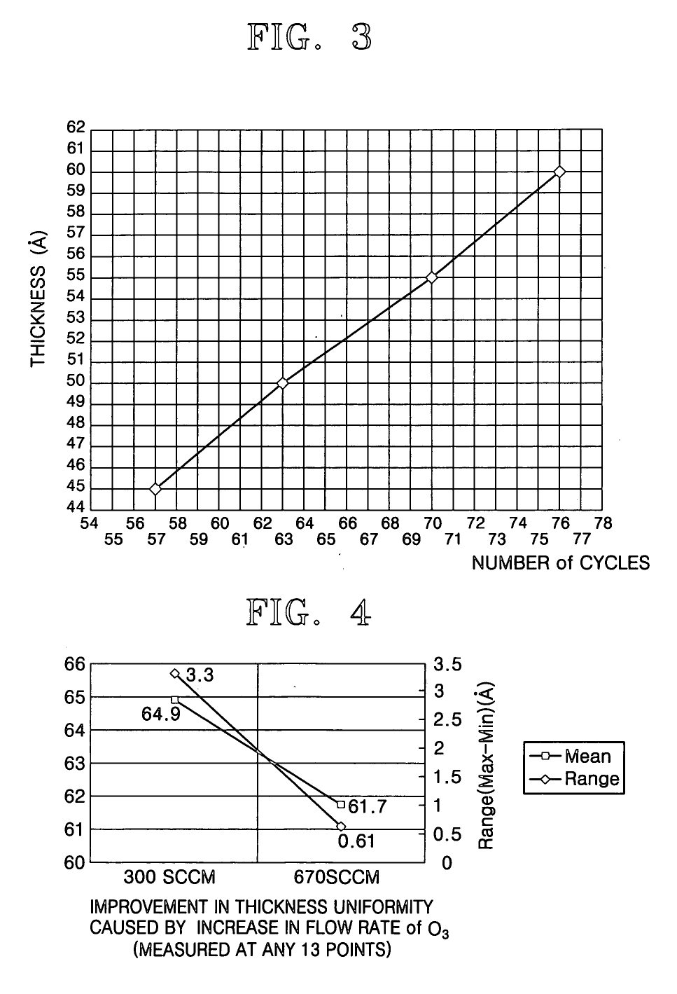

FIG. 3 is a graph showing that the thickness of a thin film is linearly proportional to the number of cycles in condition that ozone is supplied at a very high flow rate in the present invention. This graph was obtained when the flow rate of ozone was 670 sccm. Although the flow rate of ozone was high in the present invention, the thickness of the thin film can be controlled as effectively as in a conventional method performed in condition that ozone was supplied at a flow rate of 500 sccm or less.

FIG. 4 is a diagram showing that the thickness uniformity is improved as the flow rate of ozone increases in the ALD method of the present invention. Here, a case where the flow rate of ozone was 300 sccm was compared with a case where the flow rate of ozone was 670 sccm. To obtain the data shown in FIG. 4, a thin film was deposited on a wafer by repeating an ALD cycle 78 times, and then the thickness of the thin film was measured at any 13 points.

As shown in FIG. 14, when the flow rate of ozone was 300 sccm, the average thickness obtained at any 13 points was 64.9 Å and a difference between the maximum thickness and the minimum thickness was 3.3 Å. Meanwhile, when the flow rate of ozone was 670 sccm, the average thickness obtained at a 13 point was 61.7 Å and a difference between the maximum thickness and the minimum thickness was 0.61 Å.

From the data shown in FIG. 4, it can be seen that the average thickness (61.7 Å) obtained when the flow rate of ozone was 670 sccm was slightly smaller than that (64.9 Å) obtained when the flow rate of ozone was 300 sccm. However, the difference (0.61 Å) in thickness obtained when the flow rate of ozone was 670 sccm was much smaller than that (3.3 Å) obtained when the flow rate of ozone was 300 sccm. That is, as the flow rate of ozone increases, the difference between the maximum thickness and the minimum thickness decreases. Accordingly, It is seen that a high raise in the flow rate of ozone can considerably improve the thickness uniformity.

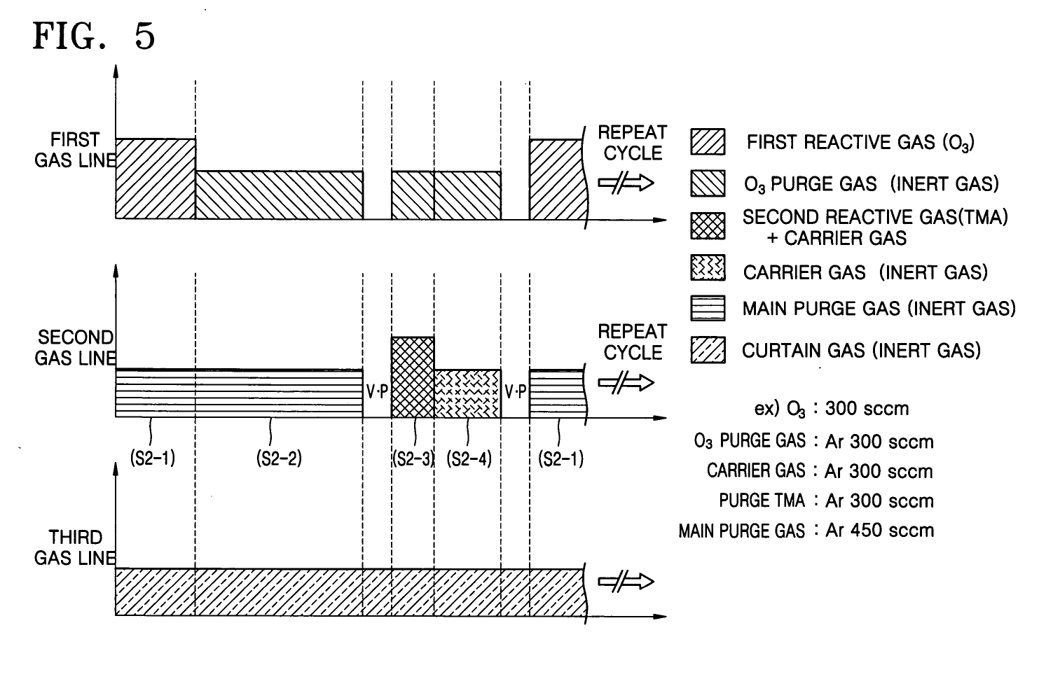

FIG. 5 is a graph illustrating a method of depositing a thin film using the apparatus of FIG. 1, according to another embodiment of the present invention. FIG. 5 illustrates a method of depositing a thin film by vacuum purging.

In the vacuum purging, while ozone is being supplied from the first reactive gas supply portion 210, all the valves installed in the gas supply portion 20, except the ozone bypass valve V3 and the valves V1 and V2 of the ozone generating unit 211, are turned off. The vacuum purging is selectively performed between any two steps of the cycle of (S2-1) feeding ozone, (S2-2) purging the ozone, (S2-3) feeding TMA, and (S2-4) purging the TMA. In the present embodiment, the vacuum purging is performed between steps (S2-2) and (S2-3). Thus, the depositing of a thin film comprises (S2-1) feeding ozone, (S2-2) purging the ozone, (V. P) vacuum purging, (S2-3) feeding TMA, and (S2-4) purging the TMA, which are sequentially performed. Unlike the first embodiment in which only the inert gas is used, both the inert gas and the vacuum purging are used in the present embodiment.

In the vacuum purging, not only the valves in the gas lines, which are directly connected to the reaction chamber 10, but also all the valves except the first valve V1, the second valve V2, and the ozone bypass valve V3 are turned off so as to prevent all the gases from flowing into the reaction chamber 10. Thus, when the gas lines allow a reactive gas to flow again, this control of the valves can prevent flow fluctuation caused by local accumulation of gases. By turning on the ozone bypass valve V3, the flow fluctuation of ozone flowing into the reaction chamber 10 can be effectively reduced. Here, it is set that the vacuum purging is performed for 0.1 second to 4 seconds. In the present invention, the vacuum purging is performed for 1 second.

In the present embodiment, the reaction chamber 10 may be a side flow type or a shower head type. However, the foregoing vacuum purging has much greater effects on a shower-head-type reaction chamber 10. That is, when the vacuum purging is performed in the shower-head-type reaction chamber 10, the step coverage and the degree of purity of resultant thin films are highly improved and the thickness of the thin films can be linearly proportional to the number of depositing cycles, as compared with when a side flow type reaction chamber is used. This is because the volume of a deposition portion of a typical shower-head-type reaction chamber is larger than that of a deposition portion of a side-flow-type reaction chamber.

If vacuum purging is appropriately used, the efficiency of purging can be increased than when only the inert gas is used. To increase the efficiency of purging, in the shower-head-type reaction chamber 10, the ozone that is sprayed before the TMA gas is sprayed should be rapidly purged from not only the top surface of the wafer but also the inside of the reaction chamber 10. This can minimize vapor deposition and leads surface saturation reactions to the wafer.

However, when the TMA gas is sprayed on the wafer, the ozone is absorbed on the surface of the wafer and also exists in space above the wafer and within the shower-head-type reaction chamber. Accordingly, the vacuum purging is further performed to exhaust the remaining reactive gas through the exhaust line 500 before the next reactive gas is supplied to the reaction chamber 10.

As explained thus far, the method of the present invention allows deposition of an aluminum oxide (Al₂O₃) film by controlling the flow rate of ozone and improves the thickness uniformity and degree of purity of the aluminum oxide (Al₂O₃) film deposited on a wafer.

What is claimed is:

1. A method of depositing a thin film on a wafer using an aluminum compound, the thin film being formed of Al₂O₃, the method being performed using a reaction chamber comprising a reactor block in which a wafer block is received; a top lid for covering the reactor block to maintain a predetermined pressure; a shower head including a plurality of first spray holes for spraying a first reactive gas supplied from a gas supply portion on the wafer and a plurality of second spray holes for spraying a second reactive gas supplied from the gas supply portion on the wafer, the method comprising:
(S1) mounting the wafer on the wafer block that is set so as to heat the wafer at a temperature of 250° C. or higher; and
(S2) depositing an Al₂O₃ thin film by alternately spraying the first reactive gas and the second reactive gas on the wafer,
step (S2) comprising:
(S2-1) feeding ozone by spraying the ozone as the first reactive gas through the first spray holes at a flow rate of from 50 sccm to 1000 sccm, the concentration of the ozone being 100 g/cm³ or higher, and, at the same time, spraying an inert gas through the second spray holes at a flow rate of 50 sccm to 1000 sccm;
(S2-2) purging the ozone by stopping the spraying of the ozone and spraying the inert gas through the first spray holes at a flow rate of 50 sccm to 1000 sccm, and, at the same time, spraying the same inert gas as in step (S2-1) through the second spray holes;
(S2-3) feeding a TMA gas by spraying the TMA gas as the second reactive gas through the second spray holes, the TMA gas being transferred by a carrier gas that is supplied at a flow rate of 50 sccm to 1000 sccm, and, at the same time, spraying the inert gas through the first spray holes at a flow rate of 50 sccm to 1000 sccm; and
(S2-4) purging the TMA gas by stopping the spraying of the TMA gas and spraying the same carrier gas as in step (S2-3) through the second spray holes and, at the same time, spraying the same inert gas as in step (S2-3) through the first spray holes,
step (S2) being performed by repeating an ALD cycle of steps (S2-1), (S2-2), (S2-3), and (S2-4) twice or more,
wherein it is set that steps (S2-1) and (S2-2) each is performed for 0.1 second to 4 seconds and steps (S2-3) and (S2-4) each is performed for 0.1 second to 3 seconds.

2. The method of claim 1, wherein the inert gas is sprayed through gas curtain holes, which are further included in the shower head, toward the inner sidewalls of the reactor block so as to minimize deposition of the thin film on the inner sidewalls of the reactor block, the inert gas being supplied at a flow rate of 50 sccm or more.

3. The method of claim 1 or 2, wherein the TMA gas is supplied from a canister that is heated at a temperature of approximately 16° C. to 40° C. and has a capacity of approximately 500 cc to 3000 cc.

4. The method of claim 1 or 2, further comprising vacuum purging, which is selectively performed between any two steps of the ALD cycle of steps (S2-1), (S2-2), (S2-3), and (S2-4),
wherein vacuum purging is performed by preventing all the gases from flowing into the reaction chamber and it is set that vacuum purging is performed for 0.1 second to 4 seconds.
